(19) United States
(12) Patent Application Publication
(10) Pub. No.: US 2021/0280398 A1
(43) Pub. Date: Sep. 9, 2021

(54) SUPPORT UNIT AND SUBSTRATE PROCESSING APPARATUS INCLUDING THE SAME

(71) Applicant: SEMES CO., LTD., Chungcheongnam-do (KR)

(72) Inventors: Seungjun Oh, Busan (KR); Su Hyung Lee, Hwaseong-si (KR); Hyun Kyu Choi, Cheonan-si (KR); Jin Woo Choi, Suwon-si (KR); Jungyoon Yang, Cheonan-si (KR)

(21) Appl. No.: 17/192,970

(22) Filed: Mar. 5, 2021

(30) Foreign Application Priority Data
Mar. 6, 2020 (KR) 10-2020-0028188

(51) Int. Cl. H01J 37/32; H05B 3/14; H05B 3/30; H05B 3/28

(52) U.S. Cl. CPC H01J 37/32724; H05B 3/143; H01J 2237/3321; H05B 3/283; H01J 37/32706; H05B 3/30

(57) ABSTRACT

A support unit includes a first plate on which a substrate is seated, a second plate located under the first plate, a third plate located under the second plate, a ground electrode disposed between the first plate and the second plate, and a heater electrode disposed between the second plate and the third plate. The first plate includes a first dielectric plate, a conductive plate disposed under the first dielectric plate, and a second dielectric plate disposed under the conductive plate.

### CROSS-REFERENCE TO RELATED APPLICATIONS

A claim for priority under 35 U.S.C. § 119 is made to Korean Patent Application No. 10-2020-0028188 filed on Mar. 6, 2020, in the Korean Intellectual Property Office, the entire contents of which are hereby incorporated by reference.

### BACKGROUND

Embodiments of the inventive concept described herein relate to a support unit and a substrate processing apparatus including the support unit, and more particularly, relate to a structure of a support unit for preventing damage caused by electric polarization between a wafer and a heater.

Semiconductor elements are manufactured through a FAB process of forming an electrical circuit pattern on a silicon substrate such as a wafer. The circuit pattern forming process may include a process of forming a metal thin film on the substrate, and the metal thin film may be formed through a deposition process. A plasma processing method capable of achieving an excellent deposition rate while forming a thin film is widely used as the deposition process. The plasma processing method may use, for example, a plasma-enhanced chemical vapor deposition (PE-CVD) apparatus.

The PE-CVD apparatus may include a housing into which a reactant gas is injected, a plasma electrode that is disposed in the housing and that generates plasma from the reactant gas to form a thin film on a substrate, and a support unit on which the substrate is seated. The support unit may include a heater.

FIG. 1 is a sectional view illustrating a heater structure 1 in a support unit in the related art.

The heater structure 1 includes an upper plate 2, an intermediate plate 3, a lower plate 4, a ground electrode 5 between the upper plate 2 and the intermediate plate 3, and a heater electrode 6 between the intermediate plate 3 and the lower plate 4.

The upper plate 2, the intermediate plate 3, and the lower plate 4 of the heater structure 1 are formed of a high-k dielectric material. Due to this, the permittivity in the heater structure 1 is measured to be high, and an influence of a charge accumulation phenomenon is increased. Therefore, a chucking phenomenon occurs between a wafer and the heater structure 1. More specifically, a chucking phenomenon by electric polarization between the wafer and the heater structure 1 occurs to cause damage to the wafer.

FIG. 2 is a view illustrating a charge accumulation phenomenon in the heater structure of the support unit of FIG. 1.

Referring to FIG. 2, a wafer W is seated on an upper surface of the heater structure 1.

In the heater structure 1, a ceramic material having good tolerance to electrical breakdown and high thermal conductivity is mainly used to prevent damage to the wafer W by leakage current of the heater electrode 6. However, in the case of using the ceramic material, due to high-insulation characteristics, a movement of electrical charges between the wafer W and the heater structure 1 is blocked, and when a process such as a plasma process that causes a potential difference between the wafer W and the heater structure 1 is performed, a capacitor loop is formed. Due to the capacitor loop, a phenomenon arises in which electrical charges are accumulated between the wafer W and the heater structure 1 through dielectric polarization.

According to the heater structure 1, the ceramic material having high-insulation characteristics has a high permittivity so that the capacitance is increased and the amount of electrical charge accumulated by dielectric polarization is further increased. A chucking force is determined depending on the amount of accumulated electrical charge, and when the degree of charge accumulation is severe, damage to the wafer W may be caused in a lift-up operation.

That is, due to the high permittivity of the high-insulation ceramic surrounding the heater electrode 6, a large amount of electrical charge is accumulated in the wafer W to cause chucking. In the heater structure 1, plasma arcing may be caused by the electrical charges accumulated in the wafer W, and the wafer W may be contaminated by an electrostatic attractive force of the charges accumulated in the wafer W.

Accordingly, a new heater structure for solving the aforementioned problems is required.

### SUMMARY

Embodiments of the inventive concept provide a support unit for preventing chucking between a wafer and a heater.

Furthermore, embodiments of the inventive concept provide a heater structure for blocking leakage current of a heater.

In addition, embodiments of the inventive concept provide a support unit for reducing the amount of electrical charge accumulated in a wafer.

The technical problems to be solved by the inventive concept are not limited to the aforementioned problems, and any other technical problems not mentioned herein will be clearly understood from this specification and the accompanying drawings by those skilled in the art to which the inventive concept pertains.

According to an embodiment, a support unit includes a first plate on which a substrate is seated, a second plate located under the first plate, a third plate located under the second plate, a ground electrode disposed between the first plate and the second plate, and a heater electrode disposed between the second plate and the third plate.

The first plate includes a first dielectric plate, a conductive plate disposed under the first dielectric plate, and a second dielectric plate disposed under the conductive plate.

According to an embodiment, the first dielectric plate and the second dielectric plate may be formed of different materials.

According to an embodiment, the second dielectric plate may have a greater dielectric strength than the first dielectric plate.

According to an embodiment, the first dielectric plate and the second dielectric plate may have different permittivities.

According to an embodiment, the first dielectric plate may have a lower permittivity than the second dielectric plate.

According to an embodiment, the first dielectric plate and the second dielectric plate may have a permittivity ranging from 4 to 9.

According to an embodiment, the first dielectric plate may be formed of BeO.

According to an embodiment, the second dielectric plate may be formed of AN.

According to an embodiment, an apparatus for processing a substrate includes a housing, a substrate support unit that is provided in the housing and that supports the substrate, a gas supply unit that supplies a process gas into the housing, and a plasma source having an electrode that generates plasma from the process gas using high-frequency power applied thereto. The substrate support unit includes a first plate on which the substrate is seated, a second plate located under the first plate, a third plate located under the second plate, a ground electrode disposed between the first plate and the second plate, and a heater electrode disposed between the second plate and the third plate. The first plate includes a first dielectric plate, a conductive plate disposed under the first dielectric plate, and a second dielectric plate disposed under the conductive plate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a heater structure in a support unit in the related art;

FIG. 2 is a view illustrating a charge accumulation phenomenon in the heater structure of the support unit of FIG. 1;

FIG. 3 is a view illustrating a substrate processing apparatus according to an embodiment of the inventive concept;

FIG. 4 is a sectional view illustrating a heater structure in a substrate support unit according to an embodiment of the inventive concept;

FIG. 5 is a view illustrating an improved charge accumulation phenomenon in the heater structure of the substrate support unit according to the embodiment of the inventive concept; and

FIG. 6 is a view illustrating a heater structure in a substrate support unit according to another embodiment of the inventive concept.

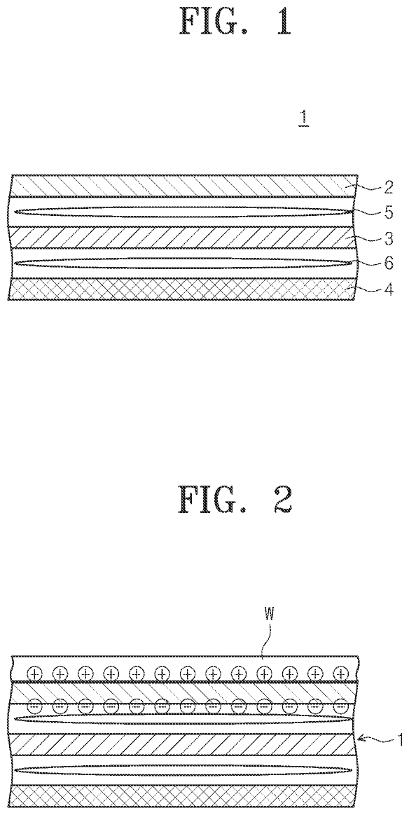

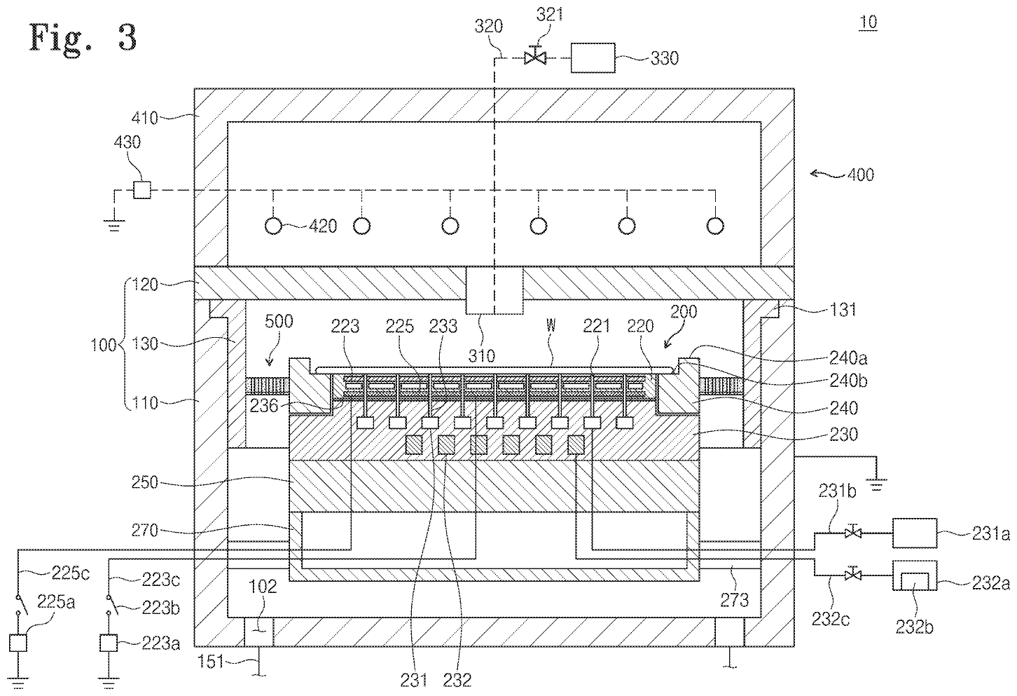

### DETAILED DESCRIPTION

Other advantages and features of the inventive concept, and implementation methods thereof will be clarified through the following embodiments to be described in detail with reference to the accompanying drawings. The inventive concept may, however, be embodied in different forms and should not be construed as being limited to the embodiments set forth herein. Rather, these embodiments are provided so that this disclosure is thorough and complete and fully conveys the scope of the inventive concept to a person skilled in the art to which the inventive concept pertains. Further, the inventive concept is only defined by the appended claims.

Even though not defined, all terms used herein (including technical or scientific terms) have the same meanings as those generally accepted by general technologies in the related art to which the inventive concept pertains. The terms defined in general dictionaries may be construed as having the same meanings as those used in the related art and/or a text of the present application and even when some terms are not clearly defined, they should not be construed as being conceptual or excessively formal.

Terms used herein are only for description of embodiments and are not intended to limit the inventive concept. As used herein, the singular forms are intended to include the plural forms as well, unless context clearly indicates otherwise. It will be further understood that the terms “comprise” and/or “comprising” used herein specify the presence of stated features or components, but do not preclude the presence or addition of one or more other features or components. In the specification, the term “and/or” indicates each of listed components or various combinations thereof.

The terms such as first, second, and the like may be used to describe various components, but the components should not be limited by the terms. The terms may be used only for distinguishing one component from others. For example, without departing the scope of the inventive concept, a first component may be referred to as a second component, and similarly, the second component may also be referred to as the first component.

The terms of a singular form may include plural forms unless otherwise specified. Furthermore, in the drawings, the shapes and dimensions of components may be exaggerated for clarity of illustration.

The inventive concept relates to an upper structure of a heater for alleviating polarization at an interface between a heater and a wafer. In the heater structure according to the inventive concept, an upper plate is formed in the form of a capacitor having a low permittivity, thereby reducing the amount Q of accumulated electrical charge. More detailed description will be given below with reference to FIG. 3 and the following drawings.

FIG. 3 is a view illustrating a substrate processing apparatus according to an embodiment of the inventive concept.

FIG. 3 is a sectional view illustrating the substrate processing apparatus according to the embodiment of the inventive concept.

Referring to FIG. 3, the substrate processing apparatus 10 processes a substrate W using plasma. For example, the substrate processing apparatus 10 may perform an etching process on the substrate W. The substrate processing apparatus 10 includes a chamber 100, a substrate support unit 200, a gas supply unit 300, a plasma source 400, and an exhaust unit 500.

The chamber 100 provides a space in which a substrate processing process is performed. The chamber 100 includes a housing 110, a cover 120, and a liner 130.

The housing 110 has an interior space that is open at the top. The interior space of the housing 110 is provided as the space in which the substrate processing process is performed. The housing 110 is formed of a metallic material. The housing 110 may be formed of an aluminum material. The housing 110 may be grounded. The housing 110 has an exhaust hole 102 formed in the bottom thereof. The exhaust hole 102 is connected with an exhaust line 151. Reaction byproducts generated in the substrate processing process and gases staying in the interior space of the housing 110 may be released to the outside through the exhaust line 151. The pressure in the housing 110 is reduced to a predetermined pressure by the exhaust process.

The cover 120 covers the open top of the housing 110. The cover 120 has a plate shape and seals the interior space of the housing 110. The cover 120 may include a dielectric substance window.

The liner 130 is provided inside the housing 110. The liner 130 has an interior space that is open at the top and the bottom. The liner 130 may have a cylindrical shape. The liner 130 may have a radius corresponding to an inside surface of the housing 110. The liner 130 is provided along the inside surface of the housing 110. The liner 130 has a support ring 131 formed on an upper end thereof. The support ring 131 is implemented with a plate in a ring shape and protrudes outward from the liner 130 along the periphery of the liner 130. The support ring 131 is placed on an upper end of the housing 110 and supports the liner 130. The liner 130 may be formed of the same material as that of the housing 110. The liner 130 may be formed of an aluminum material. The liner 130 protects the inside surface of the housing 110. Arc discharge may occur inside the chamber 100 in a process in which a process gas is excited. The arc discharge causes damage to surrounding devices. The liner 130 protects the inside surface of the housing 110, thereby preventing damage to the inside surface of the housing 110 by the arc discharge. Furthermore, the liner 130 prevents impurities generated in the substrate processing process from being deposited on the inside surface of the housing 110. In a case where the liner 130 is damaged by the arc discharge, an operator may replace the liner 130 with a new liner 130.

The gas supply unit 300 supplies the process gas into the housing 110. The gas supply unit 300 includes a gas supply nozzle 310, a gas supply line 320, and a gas reservoir 330. The gas supply nozzle 310 is installed in the center of the cover 120. The gas supply nozzle 310 has an injection hole formed in the bottom thereof. The injection hole is located under the cover 120 and supplies the process gas into the chamber 100. The gas supply line 320 connects the gas supply nozzle 310 and the gas reservoir 330. The gas supply line 320 supplies the process gas stored in the gas reservoir 330 to the gas supply nozzle 310. A valve 321 is installed in the gas supply line 320. The valve 321 opens and closes the gas supply line 320 and regulates the flow rate of the process gas that is supplied through the gas supply line 320.

The plasma source 400 is disposed over the substrate support unit 200. The plasma source 400 excites the process gas in the chamber 100 into plasma. An inductively coupled plasma (ICP) source may be used as the plasma source 400. The plasma source 400 includes an electrode 401, an antenna room 410, and a plasma power supply 430.

The antenna room 410 has a cylindrical shape that is open at the bottom. The antenna room 410 has a space inside. The antenna room 410 has a diameter corresponding to the chamber 100. A lower end of the antenna room 410 is detachable from the cover 120.

An antenna 420 is disposed in the antenna room 410. The antenna 420 may be implemented with a spiral coil wound a plurality of times. However, the shape of the antenna 420 and the number of antennas 420 may be modified in various ways. The plasma power supply 430 is connected to the antenna 420. An impedance matching box (WM) may be disposed between the plasma power supply 430 and the antenna 420. The antenna 420 receives electric power from the plasma power supply 430. For example, first RF power 431 may be applied to the antenna 420. When the first RF power 431 is applied to the antenna 420, the electrode 401 of the plasma source 400 generates plasma from the process gas.

The plasma power supply 430 may be located outside the chamber 100. The antenna 420, to which the first RF power 431 is applied, may form an electromagnetic field in the processing space of the chamber 100. The process gas is excited into plasma by the electromagnetic field.

Referring to FIG. 3, the substrate support unit 200 is located inside the housing 110. The substrate support unit 200 supports the substrate W. The substrate support unit 200 may include an electrostatic chuck 210 that clamps the substrate W using an electrostatic force. Hereinafter, the substrate support unit 200 including the electrostatic chuck 210 will be described.

The substrate support unit 200 includes the electrostatic chuck 210 and a lower cover 270. In the chamber 100, the substrate support unit 200 may be spaced apart upward from the bottom of the housing 110.

Configurations of the electrostatic chuck 210 and the like that are included in the substrate support unit 200 are the same as those of existing ones, and therefore descriptions thereabout will be omitted.

The substrate support unit 200 may include a heater 225. The substrate W is maintained at a predetermined temperature by heat generated from the heater 225.

Hereinafter, an embodiment of a heater structure in the substrate support unit 200 according to the inventive concept will be described with reference to additional drawings.

Although FIG. 3 illustrates an example that the heater 225 is buried in the substrate support unit 200, the heater 225 included in the substrate support unit 200 according to an embodiment of the inventive concept may be located on the uppermost surface of the substrate support unit 200, and the substrate W may be directly seated on a first plate included in the heater 225. Alternatively, the heater 225 according to the inventive concept may be disposed on a lower surface of an upper dielectric plate included in the electrostatic chuck 210.

The following description will be given under the assumption that the heater 225 is located on the uppermost surface of the substrate support unit 200 and the substrate W is directly seated on the first plate included in the heater 225.

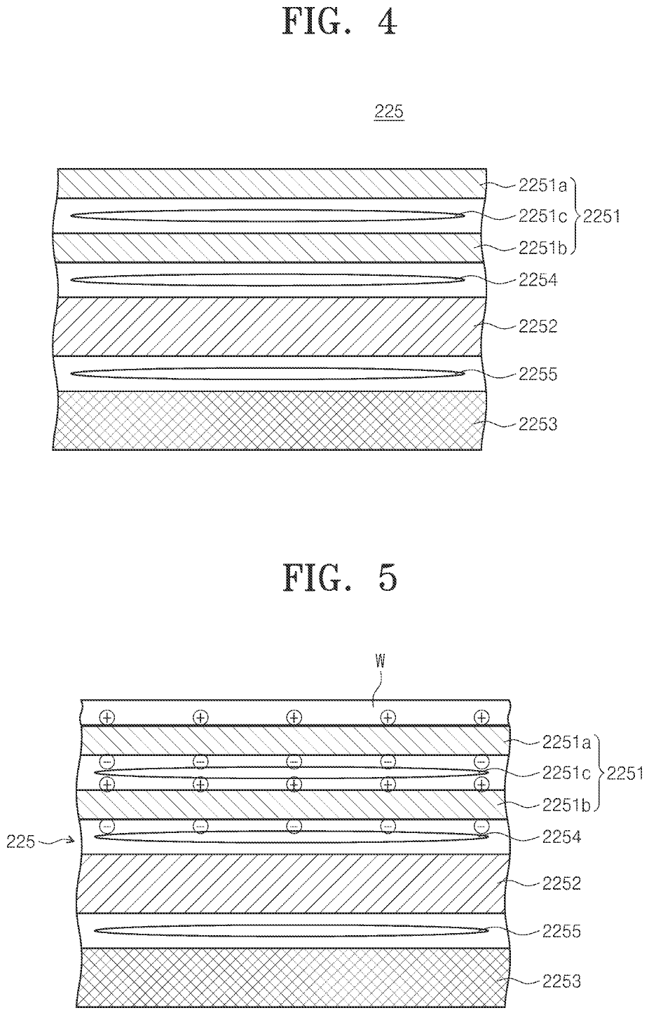

FIG. 4 is a sectional view illustrating a heater structure in the substrate support unit according to an embodiment of the inventive concept.

Referring to FIG. 4, the heater structure in the substrate support unit 200 may include a first plate 2251, a second plate 2251, and a third plate 2253 and may further include a ground electrode 2254 disposed between the first plate 2251 and the second plate 2252 and a heater electrode 2255 disposed between the second plate 2252 and the third plate 2253.

The heater electrode 2255 may be a heating wire buried in a plate. The heating wire may be arranged in a regular arrangement for each predetermined area. According to an embodiment, the heating wire may be provided in zigzags.

The ground electrode 2254 may be a plate to which a ground is connected. When current leaks out of the heater electrode 2255, the ground electrode 2254 may allow the leakage current to escape through the ground. The ground electrode 2254 may be formed of a conductive material.

The first plate 2251, the second plate 2252, and the third plate 2253 may be dielectrics. The first plate 2251, the second plate 2252, and the third plate 2253 may have a thin circular plate shape.

The first plate 2251 may have a structure in which dielectric plates 2251a and 2251b are disposed over and under a conductive plate 2251c, respectively. The first plate 2251 may include the first dielectric plate 2251a disposed in the uppermost position, the conductive plate 2251c disposed under the first dielectric plate 2251a, and the second dielectric plate 2251b disposed under the conductive plate 2251c.

According to an embodiment of the inventive concept, the conductive plate 2251c may have the shape of a flat plate or a perforated plate.

The first plate 2251 may be formed in the same structure as that of one capacitor. According to the inventive concept, the upper plate of the heater structure, that is, the first plate 2251 may be configured with the first dielectric plate 2251a, the conductive plate 2251c, and the second dielectric plate 2251b to form a series double capacitor.

That is, the upper plate of the heater structure may be formed in a multi-capacitor form to lower overall capacitance, thereby reducing the amount of electrical charge accumulated in the substrate W, which in turn prevents damage to the substrate W by chucking.

Furthermore, a dielectric used for the first dielectric plate 2251a or the second dielectric plate 2251b may have a lower permittivity than an existing one, and thus overall capacitance may be lowered. Through the adjustment of capacitance by such a structure, dielectric polarization between the substrate W and the heater 225 may be alleviated, and thus damage to the substrate W by chucking may be prevented.

According to an embodiment, the first dielectric plate 2251a and the second dielectric plate 2251b may be formed of different materials. The first dielectric plate 2251a and the second dielectric plate 2251b may be formed of materials having different dielectric strengths. The dielectric strength of the second dielectric plate 2251b may be greater than the dielectric strength of the first dielectric plate 2251a.

According to an embodiment, the first dielectric plate 2251a and the second dielectric plate 2251b may have different permittivities. The permittivity of the first dielectric plate 2251a may be lower than the permittivity of the second dielectric plate 2251b. According to an embodiment, the permittivity of the first dielectric plate 2251a located in the uppermost position may be equal to the lowest of the permittivities of the other plates included in the heater 225.

Examples of materials of which the first dielectric plate 2251a and the second dielectric plate 2251b are formed are listed in Table 1 below.

TABLE 1

| | AlN | Al2O3 | BeO | SiC | Si3N4 |
|---|---|---|---|---|---|
| Thermal Conductivity | 180 | 20 | 260 | 270 | 70 |
| (W/mK) | | | | | |
| Electric resistance | >10\hat{ }14 | >10\hat{ }14 | >10\hat{ }14 | 10\hat{ }2~10\hat{ }8 | >10\hat{ }14 |
| (Ωcm) | | | | | |
| Dielectric Strength | 150 | 100 | 100 | 0.7 | 150 |
| (kV/cm) | | | | | |
| Permittivity | 9.0 | 8.5 | 6.5 | 40 | 9.0 |

[Comparison Table of Properties of Various Materials]

The first dielectric plate 2251a and the second dielectric plate 2251b may be formed of materials having a high dielectric strength, a high thermal conductivity, a high electric resistance, and a low permittivity.

The first dielectric plate 2251a and the second dielectric plate 2251b in the heater 225 included in the substrate support unit 200 according to the inventive concept may have a permittivity ranging from 4.0 to 9.0.

According to an embodiment, a dielectric having a single structure that is used in an existing heater structure is formed of AlN, and therefore the dielectric has a permittivity of 9.0. A heater structure having a lower capacitance may be achieved by using materials having permittivities lower than 9.0 and making the permittivities of the first dielectric plate 2251a and the second dielectric plate 2251b different from each other.

According to one embodiment of the inventive concept, the first dielectric plate 2251a may be formed of BeO, and the second dielectric plate 2251b may be formed of AlN.

AlN is characterized by high insulation and high thermal conductivity, and BeO is characterized by low permittivity and high thermal conductivity. Comparing AlN and BeO in terms of dielectric strength, it can be seen that AlN has a greater dielectric strength than BeO.

According to another embodiment of the inventive concept, the first dielectric plate 2251a may be formed of AlN, and the second dielectric plate 2251b may be formed of BeO.

Both the two embodiments may obtain the same effect of preventing chucking of the substrate W by reducing capacitance.

However, in effectively blocking leakage current of the heater electrode 2255, the one embodiment in which the dielectric plate located in the lower position, that is, the second dielectric plate 2251b has a greater dielectric strength than the first dielectric plate 2251a may be more effective than the other embodiment.

In an embodiment of the heater structure according to the inventive concept, the first dielectric plate 2251a and the second dielectric plate 2251b do not have to be formed of only the materials listed in Table 1 above and may be formed of appropriate materials in the range satisfying the above-described condition.

The permittivity of the first dielectric plate 2251a may be different from the permittivity of the second dielectric plate 2251b. The permittivity of the first dielectric plate 2251a may be lower than the permittivity of the second dielectric plate 2251b. Alternatively, the permittivity of the second dielectric plate 2251b may be lower than the permittivity of the first dielectric plate 2251a. As described above, it may be effective in terms of prevention of leakage current to use a material having a high dielectric strength for the second dielectric plate 2251b.

When the first dielectric plate 2251a has the same property (e.g., dielectric strength or thermal conductivity) as the second dielectric plate 2251b, differing only in terms of permittivity, an effect of reducing capacitance may be the same irrespective of whether the permittivity of the first dielectric plate 2251a is higher or lower than the permittivity of the second dielectric plate 2251b. However, when the second dielectric plate 2251b disposed in the lower position is formed of a material having a greater dielectric strength than the material of the first dielectric plate 2251a, an effect of more assuredly blocking leakage current may be obtained.

Referring to FIG. 4, in the embodiment of the inventive concept, the plate disposed over the pattern of the heater electrode 2255 is configured with the plurality of dielectric plates 2251a and 2251b and the conductive plate 2251c disposed therebetween to alleviate polarization between the substrate W and the heater 225 inside the substrate support unit 200.

According to an embodiment of the inventive concept, at least one of the plurality of dielectric plates 2251a and 2251b included in the first plate 2251 may have a permittivity of 9 or less to reduce overall permittivity.

FIG. 5 is a view illustrating an improved charge accumulation phenomenon in the heater structure of the substrate support unit according to the embodiment of the inventive concept.

In the heater structure according to the inventive concept, the structure of the upper plate in the existing heater structure is formed in the form of a capacitor, so that the same effect as connecting a series capacitor may be obtained in terms of an overall heater. Accordingly, overall capacitance may be reduced, and the amount of accumulated electrical charge may be decreased so that charge accumulation may be alleviated. As a result, chucking of the substrate W to the heater 225 may be prevented.

In a case of using the plate structure of the heater 225 according to the inventive concept, electrostatic charges accumulated in the substrate W may be decreased, and thus plasma arcing may be prevented. In addition, contamination of the substrate W by an electrostatic attractive force may be prevented.

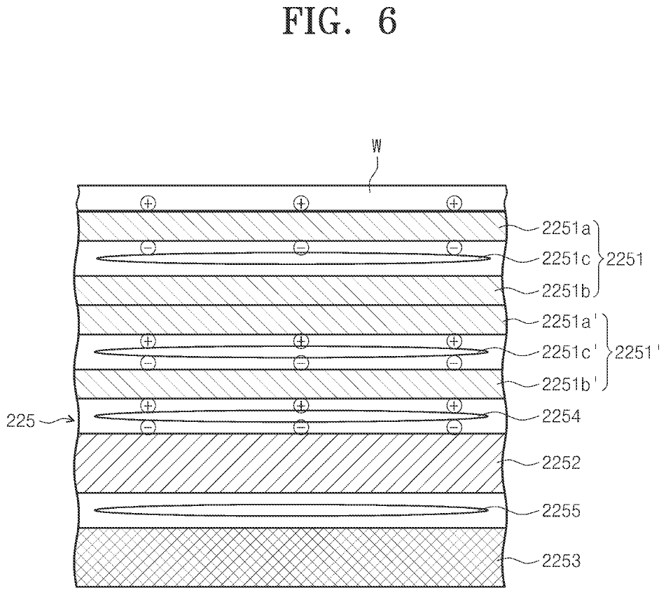

FIG. 6 is a view illustrating a heater structure in a substrate support unit according to another embodiment of the inventive concept.

The embodiment of FIG. 6 differs from the embodiment of FIG. 4 in that two first plates 2251 and 2251′, each including a first dielectric plate, a conductive plate, and a second dielectric plate, are provided in the embodiment of FIG. 6.

When a plurality of first plates, each including a first dielectric plate, a conductive plate, and a second dielectric plate, are stacked on the second plate 2252, an effect of connecting a plurality of capacitors in series may be obtained. That is, when a multi-capacitor is formed by stacking the first plates, each of which includes the first dielectric plate, the conductive plate, and the second dielectric plate, an effect of obtaining a lower capacitance value exists.

Although not illustrated in FIG. 6, additional first plates, in addition to the two first plates 2251 and 2251′, may be stacked to reduce overall capacitance.

According to the inventive concept, chucking between a wafer and the heater may be prevented by alleviating charge accumulation.

Furthermore, according to the inventive concept, damage to a wafer and contamination of the wafer may be prevented.

In addition, according to the inventive concept, leakage current caused by the heater electrode may be effectively blocked.

Effects of the inventive concept are not limited to the aforementioned effects, and any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are only drawings of the optimal embodiments of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A support unit comprising:
a first plate on which a substrate is seated;
a second plate located under the first plate;
a third plate located under the second plate;
a ground electrode disposed between the first plate and the second plate; and
a heater electrode disposed between the second plate and the third plate,
wherein the first plate includes:
a first dielectric plate;
a conductive plate disposed under the first dielectric plate; and
a second dielectric plate disposed under the conductive plate.

2. The support unit of claim 1, wherein the first dielectric plate and the second dielectric plate are formed of different materials.

3. The support unit of claim 2, wherein the second dielectric plate has a greater dielectric strength than the first dielectric plate.

4. The support unit of claim 1, wherein the first dielectric plate and the second dielectric plate have different permittivities.

5. The support unit of claim 4, wherein the first dielectric plate has a lower permittivity than the second dielectric plate.

6. The support unit of claim 5, wherein the first dielectric plate and the second dielectric plate have a permittivity ranging from 4 to 9.

7. The support unit of claim 6, wherein the first dielectric plate is formed of BeO.

8. The support unit of claim 6, wherein the second dielectric plate is formed of AlN.

9. An apparatus for processing a substrate, the apparatus comprising:
a housing;
a substrate support unit provided in the housing and configured to support the substrate;
a gas supply unit configured to supply a process gas into the housing; and
a plasma source having an electrode configured to generate plasma from the process gas using high-frequency power applied thereto,
wherein the substrate support unit includes:
a first plate on which the substrate is seated;
a second plate located under the first plate;
a third plate located under the second plate;
a ground electrode disposed between the first plate and the second plate; and
a heater electrode disposed between the second plate and the third plate, and
wherein the first plate includes:
a first dielectric plate;
a conductive plate disposed under the first dielectric plate; and
a second dielectric plate disposed under the conductive plate.

10. The apparatus of claim 9, wherein the first dielectric plate and the second dielectric plate are formed of different materials.

11. The apparatus of claim 10, wherein the second dielectric plate has a greater dielectric strength than the first dielectric plate.

12. The apparatus of claim 9, wherein the first dielectric plate and the second dielectric plate have different permittivities.

13. The apparatus of claim 12, wherein the first dielectric plate has a lower permittivity than the second dielectric plate.

14. The apparatus of claim 13, wherein the first dielectric plate and the second dielectric plate have a permittivity ranging from 4 to 9.

15. The apparatus of claim 14, wherein the first dielectric plate is formed of BeO, and the second dielectric plate is formed of AlN.

16. A support unit comprising:
a first plate on which a substrate is seated;
a second plate located under the first plate;
a third plate located under the second plate;
a ground electrode disposed between the first plate and the second plate; and
a heater electrode disposed between the second plate and the third plate,
wherein the first plate includes:
a first dielectric plate;
a conductive plate disposed under the first dielectric plate; and
a second dielectric plate disposed under the conductive plate, and wherein the first dielectric plate has a lower permittivity than the second dielectric plate.

17. The support unit of claim 16, wherein the first dielectric plate and the second dielectric plate are formed of different materials.

18. The support unit of claim 16, wherein the second dielectric plate has a greater dielectric strength than the first dielectric plate.

19. The support unit of claim 18, wherein the first dielectric plate and the second dielectric plate have a permittivity ranging from 4 to 9.

20. The support unit of claim 19, wherein the first dielectric plate is formed of BeO, and
wherein the second dielectric plate is formed of AlN.
